(19) United States
(12) Patent Application Publication
(10) Pub. No.: US 2023/0401356 A1
(43) Pub. Date: Dec. 14, 2023

(54) CONSTRUCTION INFORMATION INTEGRATION SYSTEM, CONSTRUCTION INFORMATION INTEGRATION METHOD, AND CONSTRUCTION INFORMATION INTEGRATION PROGRAM

(71) Applicant: SUMITOMO MITSUI CONSTRUCTION CO., LTD., Tokyo (JP)

(72) Inventors: Sho TAGO, Tokyo (JP); Kazuhito SUGAYA, Tokyo (JP); Takashi SUGIMOTO, Tokyo (JP); Masatoshi SOMEYA, Tokyo (JP); Kentaro TOKURA, Tokyo (JP)

(21) Appl. No.: 18/035,278

(22) PCT Filed: Mar. 8, 2021
(86) PCT No.: PCT/JP2021/008965

§ 371 Date: May 3, 2023

(30) Foreign Application Priority Data
Nov. 27, 2020 (JP) 2020-197371

(51) Int. Cl. G06F 30/20

(52) U.S. Cl. CPC G06F 30/20

(57) ABSTRACT

Provided are a construction information integration system, a construction information integration method, and a construction information integration program that properly support the automated operation of a crane. The construction information integration system 100 manages the automated operation of a crane and includes an architectural information acquiring unit 110 that acquires architectural information including information related to a design, a construction member, and a construction plan of a building to be constructed, a plan information generation unit 120 that generates, on the basis of the architectural information, first plan information including at least installation coordinates and order of installation for the construction member, and a transmission unit 130 that transmits the first plan information to a machine body control system 20 provided as a separate system from the construction information integration system 100 to control the operation of the crane.

### TECHNICAL FIELD

The present invention relates to a construction information integration system, a construction information integration method, and a construction information integration program.

### BACKGROUND ART

In general, a tower crane is used in, for example, construction of a large building, a skyscraper, and a high-rise condominium, and such a crane is used to lift and move building materials horizontally.

The tower crane has an operator cab, where the operator operates buttons and levers to operate a hoisting device to hoist a lifting wire, operate a derricking device to raise and lower a jib, and operate a slewing gear to rotate the jib.

Furthermore, in recent years, a tower crane remote control system has been developed that allows a crane to be operated from a remote location rather than from a tower crane operator cab. The tower crane remote control system can reproduce on the ground the same environment as that of the operator cab of the tower crane.

There is a feature related to an automated operation system for a tower crane that automatically controls the tower crane using, for example, a control device (see for example Patent Document 1). The automated operation system for a tower crane disclosed in Patent Document 1 includes receiving units capable of constant satellite positioning, which is provided at the top of the tower, the tip of a jib, and a hook block to enable real-time positioning of the positional relations among these elements, and while a plan view and a three-dimensional view of a building design are displayed as appropriate, the control device automatically raises and lowers the jib (including hoisting) and rotates the slewing body.

### CITATION LIST

### Patent Document

Patent Document 1: Patent Publication JP-A-2019-112178

### SUMMARY

### Technical Problem

However, in the automated operation system for a tower crane disclosed in Patent Document 1, an operator checks the plan view and the three-dimensional view of the design of the building displayed on a screen and determines the installation position of a building member (load) to touch the installation position determined on the screen. Then, on the basis of the touch by the operator, the control device automatically raises and lowers the jib and turns the slewing body.

Stated differently, in the automated operation system for a tower crane disclosed in Patent Document 1, the tower crane is partially automated, but there is still room for improvement in the technique of automated operation control of the tower crane.

It is therefore an object of the present invention to provide a construction information integration system, a construction information integration method, and a construction information integration program that properly support the automated operation of a crane.

### Solution to Problem

A construction information integration system according to one aspect of the present invention manages the automated operation of a crane and includes an architectural information acquiring unit that acquires architectural information including information related to a design, a construction member, and a construction plan of a building to be constructed, a plan information generation unit that generates, on the basis of the architectural information, first plan information including at least installation coordinates and order of installation for the construction member, and a first transmission unit that transmits the first plan information to a machine body control system provided as a separate system from the construction information integration system to control operation of the crane.

According to the aspect, the architectural information acquiring unit acquires the architectural information, the plan information generation unit generates the first plan information on the basis of the architectural information, and the first transmission unit transmits the first plan information to the machine control system provided as a separate system from the construction information integration system. In this way, the machine body control system can properly control the operation of the crane on the basis of the first plan information. Stated differently, the construction information integration system can properly support the automated operation of the crane.

In the above-described aspect, the first plan information may include restriction range information that indicates an area where entry has to be avoided and which is used by the machine body control system to calculate a path along which the construction member is transported by the crane to the installation coordinates.

According to the aspect, the first plan information includes the restriction range information, and the machine body control system can safely control the operation of the crane on the basis of the first plan information. More specifically, the construction information integration system can support the automated operation of the crane safely and more properly.

In the above-described aspect, the plan information generation unit may generate second plan information including at least an installation direction for the construction member on the basis of the architectural information, and the construction information integration system may further include a second transmission unit that transmits the second plan information to a jig control system that controls operation of a jig associated with the crane.

According to the aspect, the plan information generation unit generates the second plan information, and the second transmission unit transmits the second plan information to the jig control system. In this way, the jig control system can control the operation of the jig associated with the crane on the basis of the second plan information. Stated differently, the construction information integration system can properly support the automated operation of the crane including the operation of the jig.

In the above-described aspect, the construction information integration system may further include a first receiving unit that receives, from the machine body control system, an operation log of the crane related to an installation status of the construction member, and a progress management unit that manages progress with respect to the construction plan on the basis of the operation log of the crane.

According to the aspect, the first receiving unit receives an operation log of the crane, and the progress management unit manages progress with respect to the construction plan on the basis of the operation log of the crane. More specifically, the construction information integration system can properly support the automated operation of the crane including the progress management.

In the above-described aspect, the operation log of the crane may include information related to identification information that can be used to identify the construction member, starting time and ending time for the operation of the crane, and the installation coordinates of the construction member.

According to the aspect, since information can be grasped on a construction member basis, the construction information integration system can properly support the automated operation of the crane including the progress management on a construction member basis.

In the above-described aspect, the construction information integration system may further include a second receiving unit that receives an operation log of a jig related to an installation status of the construction member from a jig control system that controls the operation of the jig associated with the crane, and the progress management unit may manage progress with respect to the construction plan on the basis of the operation log of the jig.

According to the aspect, the second transmission unit receives an operation log of the jig, the progress management unit manages progress with respect to the construction plan on the basis of the operation log of the jig. More specifically, the construction information integration system can properly support the automated operation of the crane including the progress management in view of the operation of the jig.

In the above-described aspect, the operation log of the jig may include information related to identification information that can be used to identify the construction member, starting time and ending time for the operation of the jig, and an installation direction for the construction member.

According to the aspect, detailed information on the construction member can be grasped, the construction information integration system can properly support the automated operation of the crane including progress management in view of the detailed information on the construction member.

In the above-described aspect, the progress management unit may indicate progress including at least one of overall progress about a project, daily progress, and progress in units of floors.

According to the aspect, the progress can be managed from various viewpoints, the construction information integration system can properly support the automated operation of the crane while carrying out proper progress management.

In the above-described aspect, the construction information integration system may further include a construction member information acquiring unit that acquires construction member information related to the construction member provided with the identification information that can be used for identification, and a third transmission unit that transmits the construction member information to a terminal device.

According to the aspect, the construction member information acquiring unit acquires construction member information, and the third transmission unit transmits the construction member information to the terminal device. In this way, the construction member information can be grasped using the terminal device on the site, which can reduce errors related to attachment of the construction member and leads to improved operation efficiency.

In the above-described aspect, the construction information integration system may further include a third receiving unit that receives preparation completion information that indicates that the identification information that is provided to the construction member and that can be used to identify the construction member has been confirmed by the terminal device, and the first transmission unit may transmit, to the machine body control system, a starting instruction indicating the start of operation of the crane on the basis of the preparation completion information and the first plan information.

According to the aspect, the third receiving unit receives the preparation completion information, and the first transmission unit transmits a starting instruction to the machine body control system on the basis of the preparation completion information and the first plan information. In this way, the construction information integration system can properly support the automated operation of the crane while grasping the status on the site.

In the above-described aspect, the first plan information and the second plan information may include the same information.

According to the aspect, the plan information generation unit can generate the same information as the first plan information and the second plan information, which can simplify the processing by the construction information integration system and leads to improved production efficiency.

A construction information integration method according to one aspect of the present invention is carried out by a construction information integration system managing the automated operation of a crane, and the method includes the steps of acquiring architectural information including information related to a design, a construction member, and a construction plan of a building to be constructed, generating first plan information including at least installation coordinates and order of installation for the construction member on the basis of the architectural information, and transmitting the first plan information to a machine body control system provided as a separate system from the construction information integration system to control operation of the crane.

According to the aspect, the architectural information is acquired in the architectural information acquiring step, the first plan information is generated on the basis of the architectural information in the plan information generation step, and in the first transmission step, the first plan information is transmitted to the machine body control system provided as a separate system from the construction information integration system. In this way that machine body control system can control the operation of the crane on the basis of the first plane information. Stated differently, the construction information integration system can properly support the automated operation of the crane.

A construction information integration program according to one aspect of the present invention causes a computer to carry out a construction information integration method managing the automated operation of a crane, and the program executes the steps of acquiring architectural information including information related to a design, a construction member, and a construction plan of a building to be constructed, generating first plan information including at least installation coordinates and order of installation for the construction member on the basis of the architectural information, and transmitting the first plan information to the machine body control system provided as a separate system from the construction information integration system to control operation of the crane.

According to the aspect, the architectural information is acquired in the architectural information acquiring step, the first plan information is generated on the basis of the architectural information in the plan information generation step, and in the first transmission step, the first plan information is transmitted to the machine body control system provided as a separate system from the construction information integration system. In this way, the machine body control system can control the operation of the crane on the basis of the first plane information. Stated differently, the construction information integration system can properly support the automated operation of the crane.

### Advantageous Effects of the Invention

According to the invention, a construction information integration system, a construction information integration method, and a construction information integration program that properly support the automated operation of a crane can be provided.

### BRIEF DESCRIPTION OF DRAWINGS

FIG. 1 is a system configuration diagram of a construction information integration system 100 according to a first embodiment of the invention.

FIG. 2 is a view of a specific example of a restriction range.

FIG. 3A Is a view of a specific example of how the direction of a construction member is monitored by a sensor provided in the vicinity of a hook.

FIG. 3B is a view of a specific example of how the direction and position of a construction member are monitored by attaching two mobile stations on the construction member and using GNSS.

FIG. 4A is a view of a specific example of how overall progress and daily progress are indicated.

FIG. 4B illustrates a specific example of how the planned number of construction members to be attached and the number of actually attached construction members are indicated as overall progress.

FIG. 4C is a view of a specific example of how attaching starting time and ending time are indicated for each construction member to be attached as daily progress.

FIG. 5A is a view of a specific example of how progress by floor is indicated.

FIG. 5B is a view of a specific example of how details of progress for a selected floor are displayed.

FIG. 6 is a flowchart for illustrating the flow of processing according to a construction information integration method M100 carried out by a construction information integration system 100 according to the first embodiment of the invention.

FIG. 7 is a system configuration diagram of a construction information integration system 200 according to a second embodiment of the invention.

FIG. 8 is a view of a specific example of construction member information.

FIG. 9 is a view of a specific example of construction member information indicated at a terminal device 40.

FIG. 10 is a flowchart for illustrating the flow of processing according to a construction information integration method M200 carried out by a construction information integration system 200 according to the second embodiment of the invention.

### DESCRIPTION OF EMBODIMENTS

Hereinafter, preferred embodiments of the present invention will be described specifically in conjunction with accompanying drawings. For ease of understanding, identical members are designated with the same reference characters as far as possible among the drawings, and their descriptions may not be repeated.

### First Embodiment

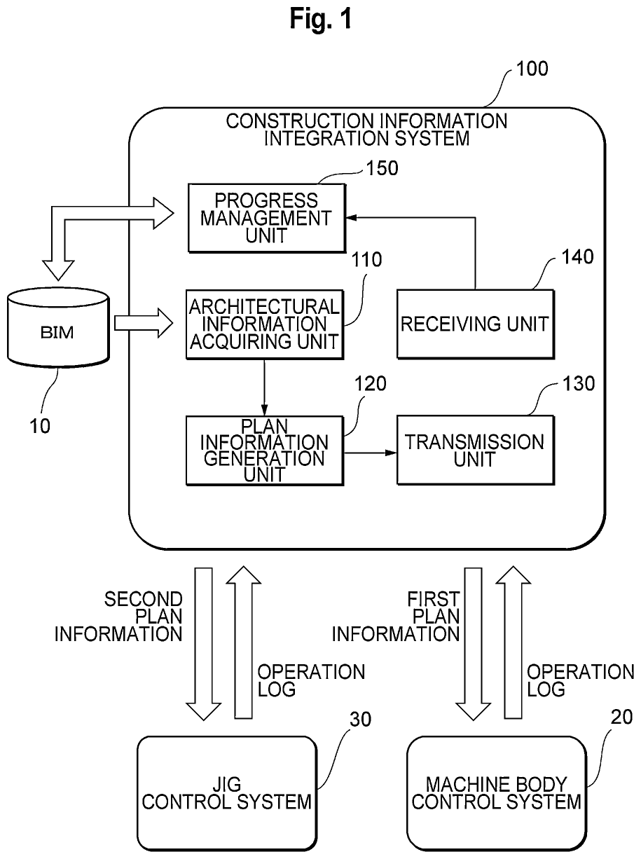

FIG. 1 is a system configuration diagram of a construction information integration system 100 according to a first embodiment of the invention. In FIG. 1, the construction information integration system 100 transmits/receives data to/from an machine body control system 20 and a jig control system 30 which are separate from the construction information integration system 100.

The machine body control system 20 controls the operation (automated operation) of the crane, and the construction information integration system 100 is configured to support the operation of the crane through the machine body control system 20. The crane controlled by the machine body control system 20 is typically a tower crane but may be any other crane such as a gantry crane, an overhead crane, a harbor container crane, and a barge crane on a ship.

The jig control system 30 controls the operation (automated operation) of a jig associated with the crane, and the construction information integration system 100 is configured to support the operation of the crane including the operation of the jig through the jig control system 30. The jig controlled by the jig control system 30 is typically a slewing gear such as a horizontal rotation jig associated with a tower crane, but the jig may be any other jig or associated with a crane other than the tower crane.

The construction information integration system 100 includes an architectural information acquiring unit 110, a plan information generation unit 120, a transmission unit 130, a receiving unit 140, and a progress management unit 150.

The architectural information acquiring unit 110 acquires architectural information including information related to the design, construction members, and a construction plan of a building to be constructed. For example, the architectural information acquiring unit 110 acquires the architectural information from information stored in BIM (Building Information Modeling).

The BIM generally includes all kinds of information, such as information on the shapes and quantities of construction members for each element of the building, added to a three-dimensional digital model created for the building. Specifically, examples of the information include a building model including site control points and the loading position, the eight outermost diameter points of a construction member, reference points, and marker position. In addition, the BIM may also include information on costs, finishes, and a construction schedule and can be used for cost and project management.

The plan information generation unit 120 generates first plan information including at least installation coordinates and order of installation for the construction members on the basis of the architectural information acquired by the architectural information acquiring unit 110. Specifically, the first plan information includes the identification information (such as IDs) of the construction members to be installed by the crane, the scheduled installation dates, and the target installation coordinates (x, y, z).

Note that the plan information generation unit 120 may use information included in the architectural information acquired by the architectural information acquiring unit 110 from the BIM as it is or may process the information as required and appropriate to generate the first plan information. The plan information generation unit 120 may generate the first plan information to conform to the interface of the machine body control system 20.

The transmission unit 130 transmits the first plan information generated by the plan information generation unit 120 to the machine body control system 20 (first transmission unit).

In this way, the machine body control system 20 controls the operation of the crane on the basis of the first plan information. For example, the machine body control system 20 calculates a path along which a construction member is to be transported to installation coordinates at a target on the basis of various kinds of information on the construction member to be installed included in the first plan information, and the system controls the operation of the crane according to the information related to the path, the scheduled installation date, and the order of installation.

The plan information generation unit 120 may generate the first plan information including restriction range information. The restriction range information indicates an area to avoid entry when the machine body control system 20 calculates the path along which the construction member is transported by the crane to the installation coordinates and may include multiple kinds of coordinate (x, y, z) information each representing the outer diameter of the restriction range.

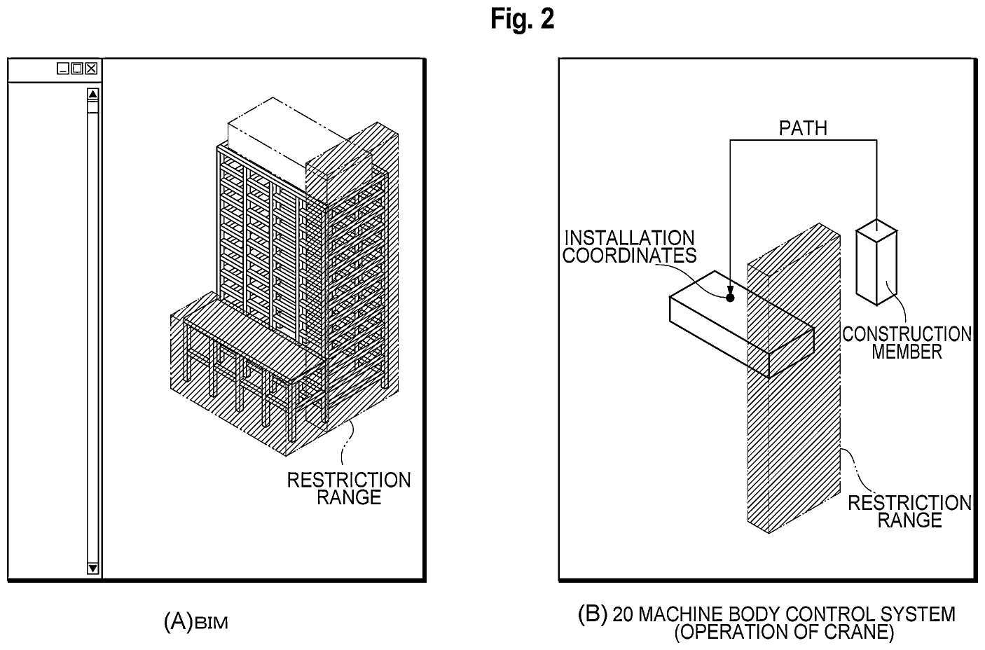

FIG. 2 is a view of a specific example of the restriction range. For example, as shown in FIG. 2, in the BIM, the restriction range, which the crane and the construction members should avoid entering, is calculated on the basis of scaffolding and floor information.

Note that as the building construction progresses day by day, site conditions may change, for example by the placement of materials on the floor, the addition or removal of scaffolding, and delivery of new mechanical materials, so that the restriction range may change accordingly. Note that the restriction range may be updated on the basis of the operation logs of the crane and the jig which will be described when the site conditions are updated, such as when scaffolding or floor information stored in the BIM is updated. In this way, the construction members can be installed at the installation coordinates while avoiding the restriction range properly.

As for the crane, the boom may be positioned using GNSS (Global Navigation Satellite System), and the operation of the crane may be monitored in real time.

The real time monitoring using GNSS allows the construction member to be installed at the installation coordinates with high precision while avoiding the restriction range properly when the construction member is transported to the installation coordinates by the crane.

The plan information generation unit 120 generates second plan information including at least the installation direction of the construction member on the basis of the architectural information acquired by the architectural information acquiring unit 110. Specifically, the second plan information includes the identification information (such as ID) and the installation direction of the construction member as a target to be controlled by the jig associated with the crane.

Note that, similarly to the first plan information, the plan information generation unit 120 may use information included in the architectural information acquired from the BIM by the architectural information acquiring unit 110 as it is or the second plan information may be generated by processing the information as required and appropriate. The plan information generation unit 120 may generate the second plan information to conform to the interface of the jig control system 30.

The plan information generation unit 120 may generate the first plan information and the second plan information to include the same information and generate one kind of plan information to conform to both the machine body control system 20 and the jig control system 30. This eliminates the need to generate multiple kinds of plan information, which simplifies the process and improves the production efficiency.

The transmission unit 130 transmits the second plan information generated by the plan information generation unit 120 to the jig control system 30 (second transmission unit).

In this way, the jig control system 30 controls the operation (automated operation) of the jig associated with the crane on the basis of the second plan information. For example, the jig control system 30 controls the installation direction of the construction member on the basis of various kinds of information about the construction member to be installed included in the second plan information. Here, the installation direction refers to the direction on the horizontal plane (east, west, south, and north), and may further include an inclination (slant).

The second plan information may include the restriction range information described above with reference to FIG. 2, and the jig control system 30 controls the operation of the jig on the basis of the restriction range information. For example, the jig control system 30 controls the operation of the jig so that the direction of the construction member is changed or the timing for the direction change is adjusted depending upon the shape, and thus the construction member can be installed in the installation direction while avoiding the restriction range properly.

When the jig having its operation controlled by the jig control system 30 is a slewing gear such as a horizontal rotation jig associated with a tower crane, a sensor may be provided in the vicinity of a hook for suspending the construction member, so that the direction of the construction member may be monitored.

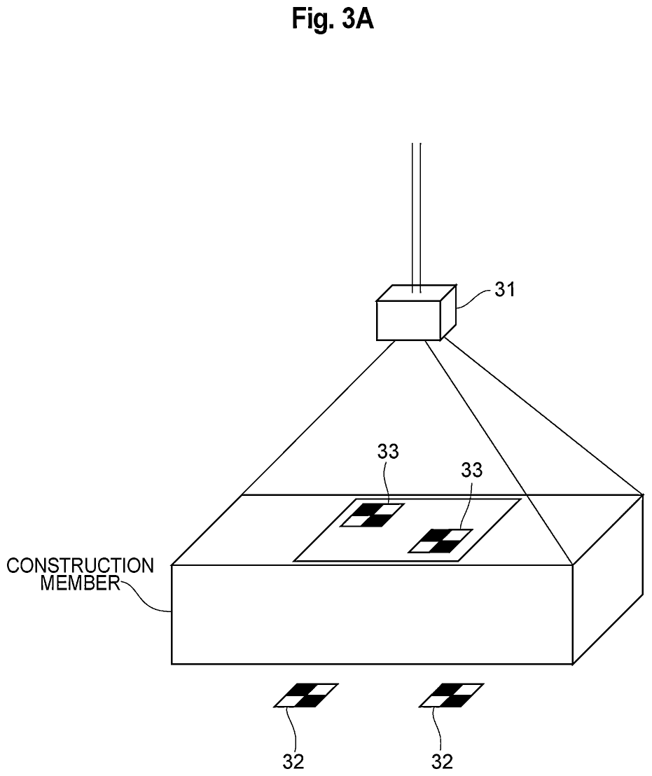

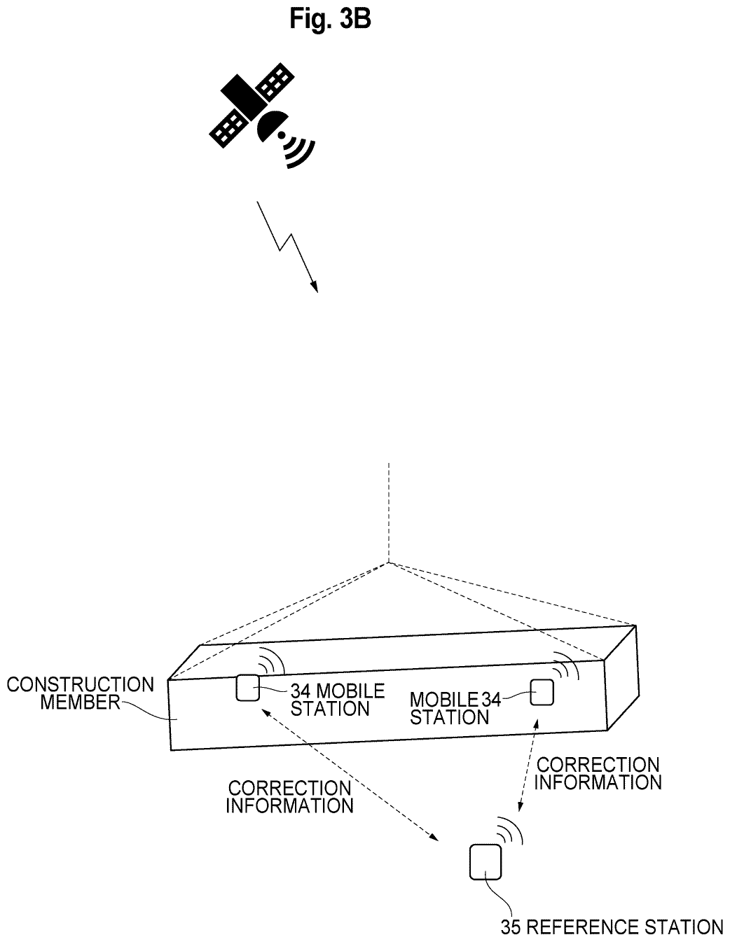

FIG. 3A is a view of a specific example of how the direction of the construction member is monitored by the sensor provided in the vicinity of the hook. In FIG. 3A, a sensor 31 is provided in the vicinity of the hook that suspends the construction member, two reference direction markers 32 are provided in the south-north direction or the east-west direction, and two direction finding markers 33 are provided on the upper surface of the construction member.

The sensor 31 may include a TOF camera (Time-of-Flight Camera) and a digital camera and measures the construction member suspended from the hook at prescribed time intervals. Here, the two reference direction markers 32 and the two direction finding markers 33 are compared, so that the direction and position of the construction member can be determined.

For example, a positioning system such as GNSS (Global Navigation Satellite System) may be used as means for determining the direction and position of the construction member.

FIG. 3B is a view of a specific example of how the direction and position of the construction member are monitored by attaching two mobile stations to the construction member and using GNSS. As shown in FIG. 3B, two mobile stations 34 are attached to the construction member, a reference station (a fixed station) 35 is provided in the vicinity, and a positioning system using RTK (Real Time Kinematic) is used.

Using the two mobile stations 34 and the reference station 35, a signal is received from the positioning satellite to obtain positioning information. The positioning information is exchanged between the two mobile stations 34 and the reference station 35, and position information with higher precision is obtained by correcting the positional shift. The reference station and the two mobile stations communicate for example by Wi-Fi®. Using a high precision positioning system such as RTK, the direction and position of a construction member can be determined with high accuracy without being affected by backlighting and bad weather.

Note that RTK is described here as a positioning system to determine the direction and position of the construction member, but any other positioning system can be used as long as the direction and position of the construction member can be determined.

In this way, the direction and position of the construction member suspended from the hook are monitored in real time using the sensors and the positioning system. This allows for more accurate installation of the construction member when the member is transported by the crane and the jig associated with the crane to the installation coordinates and installed in the target installation direction.

The receiving unit 140 receives, from the machine body control system 20, a crane operation log related to the installation status of the construction member (first receiving unit). For example, the crane operation log includes identification information that can be used to identify the construction member, the starting time and ending time of the crane operation, and information about the installation coordinates of the construction member, and when the crane completes the installation of the construction member, the crane operation log is sent by the machine body control system 20.

The progress management unit 150 manages the progress with respect to the construction plan on the basis of the crane operation log received by the receiving unit 140. The progress management unit 150 reflects the construction performance in be BIM on the basis of information included in the crane operation log and manages the progress by comparing information related to the construction plan stored in the BIM and the construction result.

Note that the progress management unit 150 may reflect the information included in the crane operation log in the BIM as it is or process the information as required and as appropriate. The progress management unit 150 may also have another system process the information included in the crane operation log as appropriate to display the progress visually or from various angles, as will be described.

The progress management unit 150 displays progress, including at least one of overall project progress, daily progress, and progress by floor.

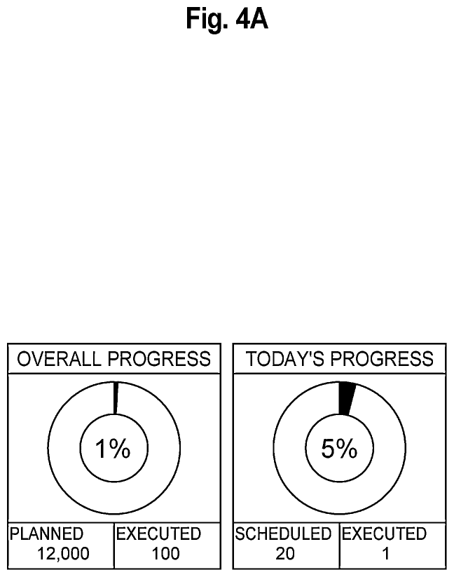

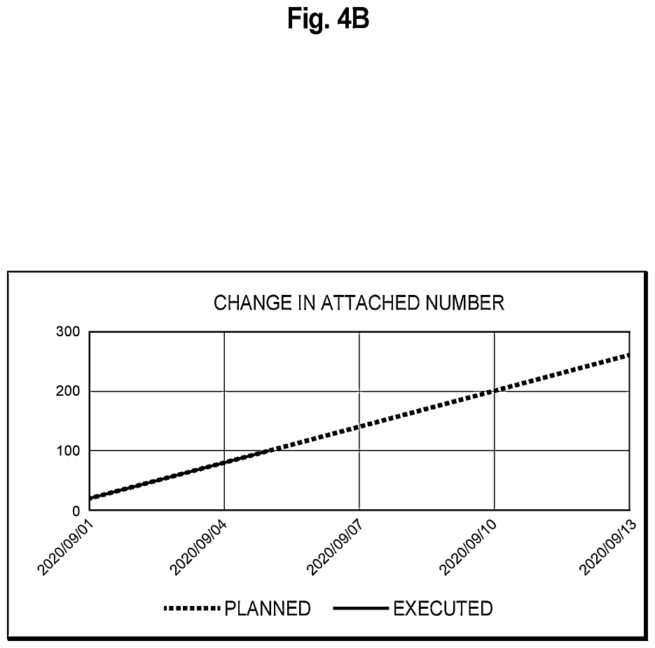

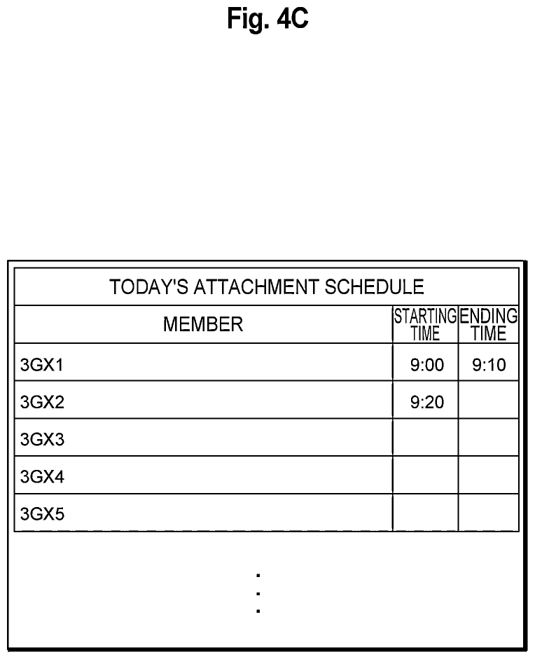

FIG. 4A illustrates a specific example of overall progress and daily progress. In FIG. 4A, the overall progress is indicated by a pie chart showing the number of members actually installed relative to the number of members planned to be installed. The daily progress is indicated by a pie chart showing the number of actually installed members relative to the planned number of members to be installed that day.

Note that the ratio of the installed number to the planned number is indicated using the pie charts for ease of visual understanding, but a bar chart may be used, or different display colors may be used depending on the degree of progress (such as ahead of schedule, on schedule, behind schedule).

FIG. 4B illustrates a specific example of the number of construction members planned to be installed and the number of actually installed construction members as overall progress. In FIG. 4B, the accumulation of planned and actually installed numbers is indicated in chronological order. In this way, the number of installed construction members can be monitored, so that the overall progress can be easily grasped visually.

FIG. 4C is a view of a specific example of how installation starting time and ending time for each member to be installed is indicated as daily progress. In FIG. 4C, the installation starting time and ending time are indicated for each installation member to be installed that day as an installation (construction) result. This allows the user to easily grasp which of the installation members has been installed that day, the length of time required for the installed members, and so on.

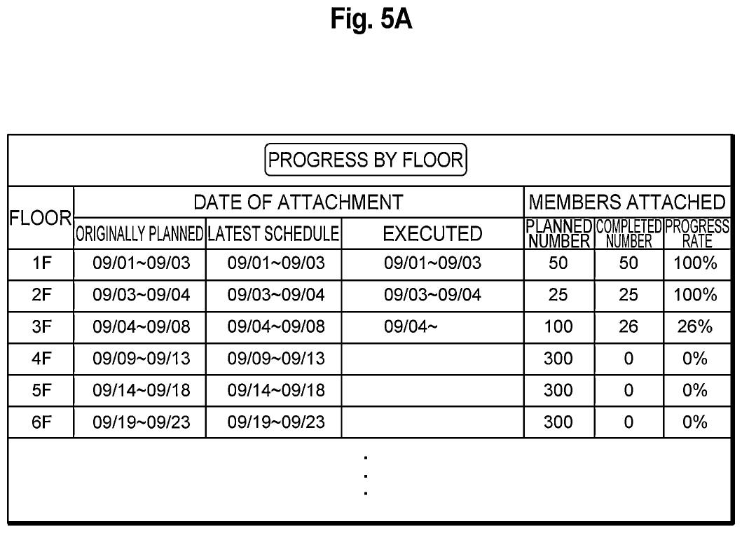

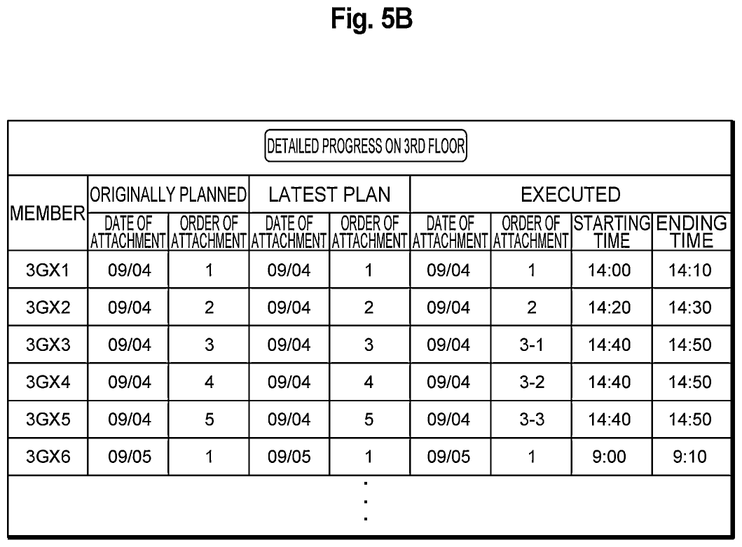

FIG. 5A illustrates a specific example of how progress by floor is indicated. In FIG. 5A, the installation period (planned and executed), the number of construction members planned to be installed and the number of actually installed members, and the progress rate are displayed for each floor, starting from the first floor. Regarding the installation period, the plan may be moved forward or delayed as the actual construction progresses, and in such cases, the original plan is revised as the latest schedule. The plan information generation unit 120 may generate first and second plan information on the basis of the revised plan.

FIG. 5B illustrates a specific example of how details of the progress of a selected floor are indicated. In FIG. 5B, for example, “3F” shown in FIG. 5A is selected and the progress details of the third floor are displayed. Specifically, for each construction member to be installed on the third floor, the date of installation, starting time, and ending time are indicated as an installation result.

According to FIGS. 5A and 5B, the progress by floor can be easily grasped as a whole, and details of the progress for each floor can also be grasped.

The screens for indicating the progress shown in FIGS. 4A to 4C, 5A, and 5B are not limited to these, and contents, items, and a display style may be added, deleted, or changed as necessary according to the user and the situation.

The screens shown in FIGS. 4A to 4C, FIG. 5A and FIG. 5B may each be displayed as a single screen, or all or some of the screens may be combined and displayed as a single screen. The arrangement of the screens may be set according to the user's needs, and furthermore, the settings may be changed.

Furthermore, in addition to receiving the crane operation log from the machine body control system 20, the receiving unit 140 may also receive a jig operation log regarding the installation status of the construction member from the jig control system 30 (second receiving unit). For example, the jig operation log includes identification information that can be used for identifying the construction member, the starting time and ending time for the operation of the jig, and information regarding the installation direction of the construction member, and when the installation of the construction member is completed by the crane and jig, the jig operation log is sent from the jig control system 30.

The progress management unit 150 may manage progress with respect to the construction plan on the basis of the jig operation log in addition to the crane operation log received by the receiving unit 140. For example, the progress management unit 150 may reflect the information included in the crane operation log as a construction result in the BIM on the basis of the information included in the jig operation log in addition to the information included in the crane operation log, and furthermore, the progress may be managed by comparing the information about the construction plan stored in the BIM with the construction result.

In addition to the information included in the crane operation log, the information included in the jig operation log can be used to grasp the status in more detail. For example, the progress described with reference to FIGS. 4A to 4C, FIGS. 5A and 5B can be displayed in more detail.

Furthermore, although the progress management unit 150 mainly manages progress related to the installation status of the construction member on the basis of the crane operation log and the jig operation log, the unit can also manage progress related to the generation and transmission of other kinds of information, for example, the first plan information, the second plan information, and construction member information which will be described. More specifically, the progress management unit may manage whether the generation of the first and second plan information has been completed, whether the transmission of the first plan information to the machine body control system 20 has been completed, whether the transmission of the second plan information to the jig control system 30 has been completed, or more specifically, whether the restriction range information has been calculated, and whether the restriction range information has been transmitted to the machine body control system 20 and the jig control system 30.

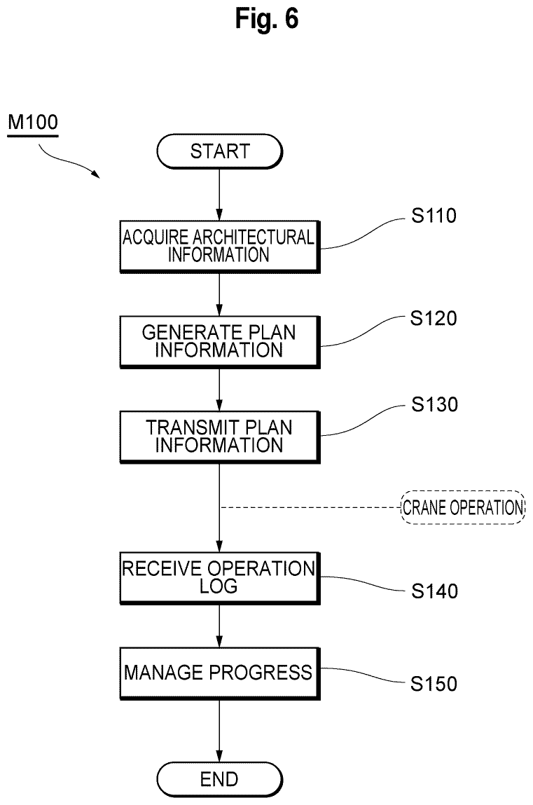

FIG. 6 is a flowchart for illustrating the flow of processing according to a construction information integration method M100 executed by the construction information integration system 100 according to the first embodiment of the present invention. In FIG. 6, the construction information integration method M100 includes steps S110 to S150 executed by a processor included in the construction information integration system 100.

In step S110, the architectural information acquiring unit 110 acquires architectural information. For example, the architectural information acquiring unit 110 acquires the architectural information from information stored in the BIM.

In step S120, the plan information generation unit 120 generates first plan information (second plan information) on the basis of architectural information obtained in step S110. For example, the plan information generation unit 120 checks the information included in the architectural information obtained from the BIM for data omissions and format deficiencies. In this way, the plan information generation unit 120 appropriately generates the first plan information (second plan information) on the basis of the architectural information obtained in step S110, for example, to conform to the interface of the machine body control system 20 (jig control system 30).

Typically, information on the construction members and construction plan are stored in the BIM in advance, and the first plan information (second plan information) is generated appropriately by using the information as it is or by processing the information while checking these kinds of information for data omissions and formatting errors.

Meanwhile, the plan information generation unit 120 may also generate the first plan information (second plan information) by acquiring information on the construction members and construction plan from any system other than the BIM and using the information as it is or by processing the information. For example, the plan information generation unit 120 generates the first plan information (second plan information) on the basis of information generated using general-purpose application software. Since the information necessary to generate the first plan information (second plan information) can be created using the general-purpose application software, even a user without specialized advanced operation skills or knowledge thereof can easily use the construction information integration system 100. The convenience of the construction information integration system 100 is improved because data can be modified and changed using familiar application software.

In step S130, the transmission unit 130 transmits the first plan information (second plan information) generated in step S120 to the machine body control system 20 (jig control system 30).

In step S140, the receiving unit 140 receives the crane operation log (jig operation log) from the machine body control system 20 (jig control system 30). For example, the machine body control system 20 (jig control system 30) transmits the crane operation log (jig operation log) to the construction information integration system 100 when the crane (jig) has completed installation of the construction member. The receiving unit 140 then receives the crane operation log (jig operation log).

In step S150, the progress management unit 150 manages the progress with respect to the construction plan on the basis of the crane operation log (jig operation log) received in step S140. For example, the progress management unit 150 reflects the construction result in the BIM and manages the progress by comparing the construction plan stored in the BIM with the construction result. The progress management unit 150 displays a screen showing the progress status so that it is easy for the user to visually grasp the status.

The progress management unit 150 may reflect the construction result in the BIM and have any other system such as the BIM perform the processing of displaying a screen showing the progress status.

As described above, according to the construction information integration system 100 and the construction information integration method M100 according to the first embodiment of the invention, the architectural information acquiring unit 110 acquires construction information, the plan information generation unit 120 generates first plan information (second plan information) on the basis of the construction information, and the transmission unit 130 transmits the first plan information (second plan information) to the machine body control system 20 (jig control system 30), which is a separate system from the construction information integration system 100. This allows the machine body control system 20 to control the crane operation on the basis of the first plan information, and the jig control system 30 to control the jig operation on the basis of the second plan information. In other words, the construction information integration system 100 can properly support the automated operation of the crane (jig).

Furthermore, the receiving unit 140 receives the crane operation log (jig operation log), and the progress management unit 150 manages the progress on the basis of the crane operation log (jig operation log). This allows the construction information integration system 100 to properly support the crane (jig) operation, including progress management. In addition, since the progress management unit 150 displays a screen showing the progress status, it is easy for the user to visually grasp the progress status.

According to the embodiment, the construction information integration system 100 transmits and receives data to and from the machine body control system 20, which controls the operation of one crane, and the jig control system 30, which controls a jig associated with the crane, but the machine body control system 20 and the jig control system 30 can transmit and receive data between each other.

For example, the construction information integration system 100 and the machine body control system 20 exchange data between each other, and the jig control system 30 and the machine body control system 20 exchange data between each other. The first plan information transmitted by the construction information integration system 100 to the machine body control system 20 can include information about the installation direction of the construction member (second plan information) that is to be used by the jig control system 30. The jig operation log of the jig control system 30 may also be included in the crane operation log of the machine body control system 20 and may be transmitted from the machine body control system 20 to the construction information integration system 100.

When the crane and the jig associated with the crane are operated, the crane and the jig can be controlled more properly by exchanging data between the machine body control system 20 and the jig control system 30.

In order to control the operation of multiple cranes, the construction information integration system 100 may exchange data with each of the machine body control systems that control the cranes or data may be exchanged among the cranes. In any case, since data is integrated and managed in the construction information integration system 100, even when the operation of multiple cranes is controlled, the operation of the cranes can be controlled properly in time series and mutual interference can be reduced.

### Second Embodiment

Now, in the following description of a second embodiment of the present invention, in addition to the construction information integration system 100 according to the first embodiment, a construction member information acquiring unit for acquiring and checking construction member information and a terminal device will be described. The configuration that differs from the first embodiment of the invention will be described in detail, and matters identical to the first embodiment of the invention will not be described or described in a simplified manner.

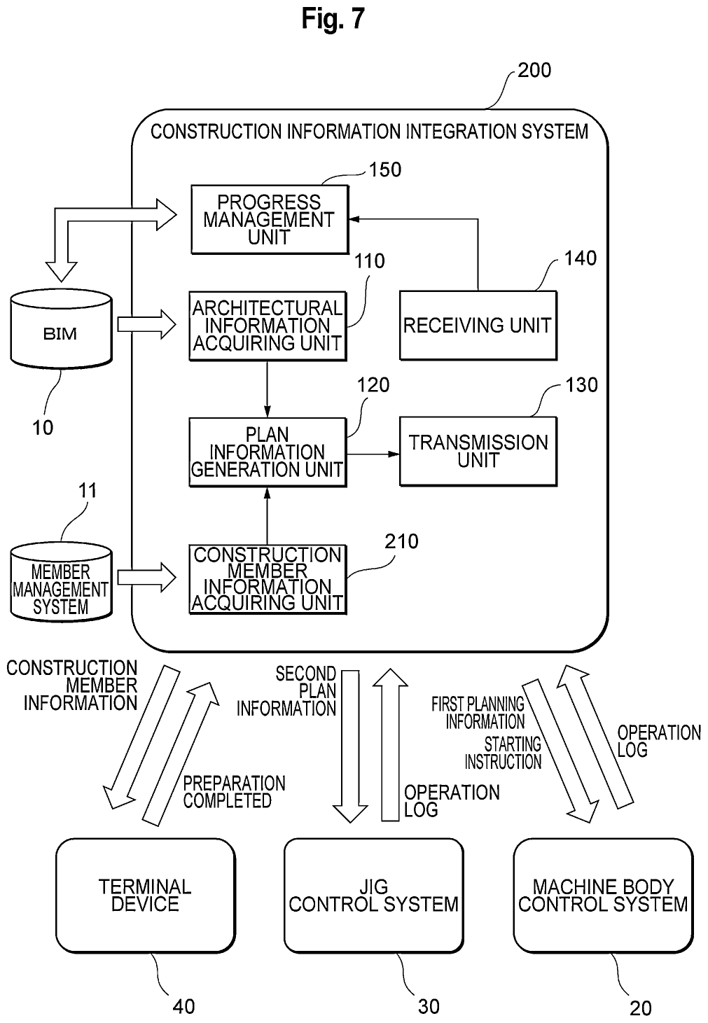

FIG. 7 is a system configuration diagram of a construction information integration system 200 according to the second embodiment of the invention. In FIG. 7, the construction information integration system 200 transmits and receives data to and from a machine body control system 20, a jig control system 30, and a terminal device 40.

The terminal device 40 is a terminal device carried by an operator working on the site, such as a tablet, a smart phone, and any other portable terminal device with a display screen. The terminal device 40 receives construction member information, which will be described, from the construction information integration system 100 and displays the information on the display screen of the terminal device 40, reads an RFID tag attached to the construction member, and transmits, to the construction information integration system 100, information indicating that construction preparation has been completed.

The construction information integration system 200 includes an architectural information acquiring unit 110, a plan information generation unit 120, a transmission unit 130, a receiving unit 140, a progress management unit 150, and a construction member information acquiring unit 210.

The construction member information acquiring unit 210 acquires construction member information on a construction member provided with identification information which can be used for identification. For example, the construction member information acquiring unit 210 acquires construction member information stored in a member management system 11. Examples of the construction member information includes identification information (such as ID), the property name, the building name, the floor number, the construction member name, and the construction part drawing.

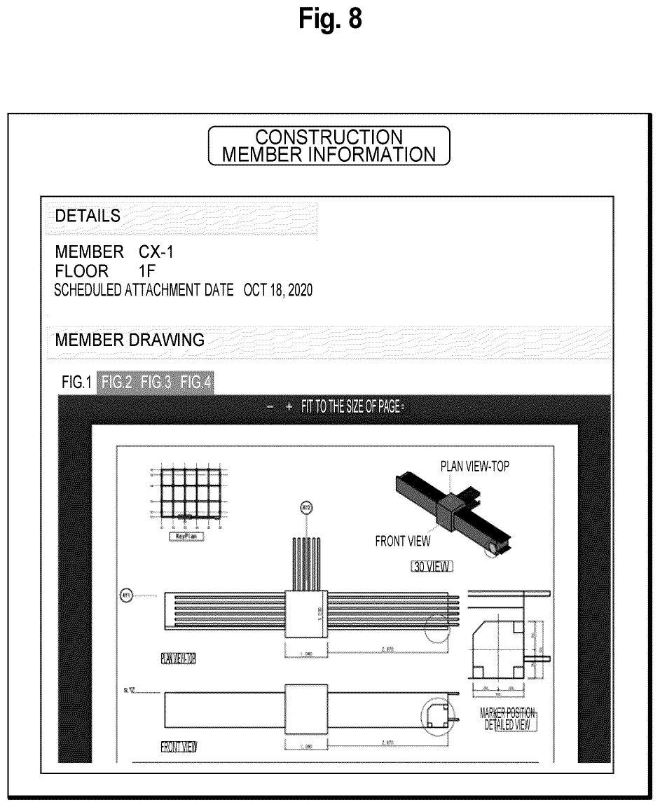

FIG. 8 is a view of a specific example of construction member information. In FIG. 8, the information and drawings related to the construction member are displayed on the screen, and in the construction information integration system 200, the screen display makes it possible to check the information and drawings related to the construction member, the status of the construction member information, whether the construction member information related to the construction member has been obtained from the member management system 11 or transmitted to the terminal device 40 or to the machine body control system 20 or whether the installation of the construction member has been completed.

The plan information generation unit 120 generates first plan information on the basis of the construction information acquired by the architectural information acquiring unit 110 and construction member information acquired by the construction member information acquiring unit 210. The plan information generation unit 120 may generate the first plan information including at least installation coordinates and order of installation for the construction member on the basis of the architectural information and add the construction member information separately as in the description of the first embodiment.

In either case, specific and detailed information on the construction members can be added to the installation coordinates and the order of installation for the construction member.

The transmission unit 130 transmits the construction member information to the machine body control system 20 together with or separately from the first plan information. The machine body control system 20 may control the crane operation on the basis of the construction member information included in or added to the first plan information. For example, the machine body control system 20 calculates the path along which the construction member is transported to the target installation coordinates on the basis of the construction member information included in or added to the first plan information, but the path may be calculated more accurately because specific and detailed information about the construction member can be acquired.

The plan information generation unit 120 can also more accurately grasp the restriction range on the basis of the construction member information. As a result, the machine body control system 20 can control the crane operation more properly.

The transmission unit 130 transmits the construction member information to the terminal device 40 (third transmission unit). For example, the transmission unit 130 may transmit the construction member information in response to a request from the terminal device 40 or may transmit the construction member information on the construction member on the scheduled installation date included in the first plan information at a prescribed date and time.

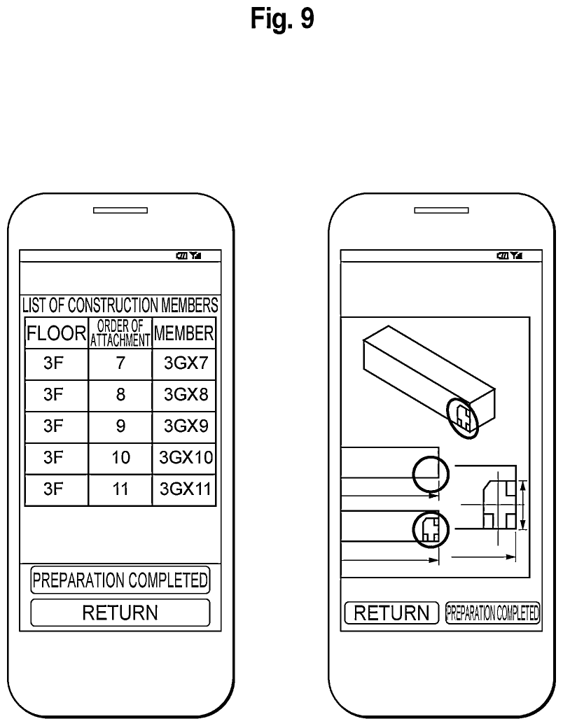

FIG. 9 is a view of a specific example of the construction member information displayed on the terminal device 40. As shown in FIG. 9, for example, construction member information for each scheduled installation date and floor is listed, and when one kind of the listed construction member information is selected by the operator, construction member information and a drawing for the selected construction member are displayed. In this way, the operator can check the construction member information received by the terminal device 40.

In addition, construction members that are transported to a construction site are given unique identification information using, for example, RFID tags. On the site, the operator reads the RFID tag attached to the construction member using an RFID tag reader included in the terminal device 40 or as a discrete device. In this way, the possibility of the crane installing a mistaken construction member is reduced.

Furthermore, on the construction site, the operator attaches a construction member to the hook of the crane as preparation for lifting the construction member to be lifted by a crane. Here, the operator notifies the construction information integration system 200, for example, by pressing the “Ready” button of the terminal device 40, that the construction member has been attached to the hook of the crane and the preparation for lifting has been completed.

The receiving unit 140 receives preparation completion information indicating that the identification information provided to the construction member that can be used to identify the construction member has been confirmed by the terminal device 40 (third receiving unit).

The transmission unit 130 transmits, to the machine body control system 20, a starting instruction indicating that operation of the crane is to be started on the basis of the preparation completion information and the first plan information. In response to the received starting instruction, the machine body control system 20 starts the operation of the crane and controls the operation of the crane so that the construction member attached to the hook is transported to the installation coordinates.

The operator may also carry out operation on the site to provide a marker, for example, as preparation for lifting. The marker is provided to monitor the direction of the construction member as described in connection with the first embodiment with reference to FIG. 3A and is preferably affixed at an appropriate location on the site before the construction member is suspended.

For example, on the site, the operator affixes the direction finding markers 33 at appropriate positions on the construction member to be suspended, in accordance with the reference direction markers 32 as shown in FIG. 3A. On the display screen of the terminal device 40, a drawing of the construction member may be displayed while specific detailed procedures for affixing the markers, such as the marker type, attaching positions, and attaching procedure may also be displayed.

When a positioning system such as GNSS as described with reference to FIG. 3B is used as means to monitor the direction and position of the construction member, the operator may attach mobile stations 34 to the construction member as part of the lifting preparation on the site. The number of the mobile stations 34 to be attached to the construction member is not limited to two, but may be one, three or more. The number needs only be set as appropriate for example according to the type, size, shape, and required direction and positional accuracy of the construction member.

The transmission unit 130 may also transmit a starting instruction to the jig control system 30 in the same manner.

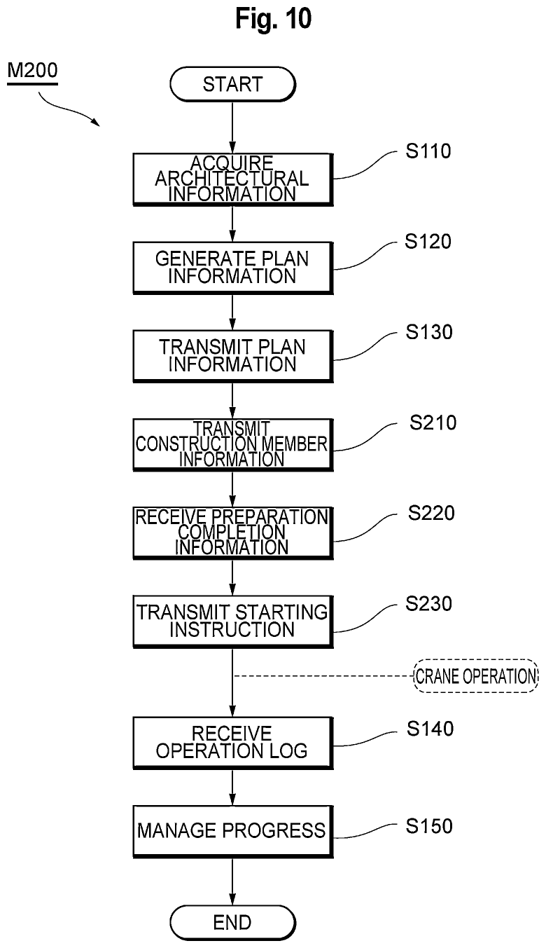

FIG. 10 is a flowchart for illustrating the flow of the processing according to a construction information integration method M200 executed by the construction information integration system 200 according to the second embodiment of the invention. In FIG. 10, the construction information integration method M200 includes steps S110 to S150 and steps S210 to S230 executed by a processor included in the construction information integration system 200. As compared to the construction information integration method M100 according to the first embodiment described with reference to FIG. 6, the construction information integration method M200 includes steps S210 to S230 before the operation of the crane.

In step S210, the transmission unit 130 transmits the construction member information to the terminal device 40. Specifically, the transmission unit 130 transmits, to the terminal device 40, construction member information on a construction member scheduled to be installed that day in response to a request from the terminal device 40 or at a prescribed date and time.

In step S220, the receiving unit 140 receives preparation completion information. For example, after the operator on the site completes preparations for lifting by attaching markers to the construction member to be lifted and attaching the member to the hook, the operator operates the terminal device 40 to transmit the preparation completion information to the construction information integration system 100. The receiving unit 140 receives the preparation completion information from the terminal device 40.

In step S230, the transmission unit 130 transmits a starting instruction. For example, on the basis of the preparation completion information received by the receiving unit 140, the transmission unit 130 transmits a starting instruction to the machine body control system 20 to lift the construction member which has its preparation completed.

Here, the construction information integration system 200 transmits, to the machine body control system 20, the first plan information and restriction range information included therein and the construction member information acquired from the member management system 11 by the construction member information acquiring unit 210, and after determining that these kinds of information have been transmitted to the machine body control system 20, the starting instruction may be transmitted to the machine body control system 20.

In this way, the operation of the crane can be prevented from being started in a situation where the first plan information or the restriction range information has not been properly transmitted from the construction information integration system 200 to the machine body control system 20.

The transmission unit 130 may also transmit the starting instruction to the jig control system 30, or the jig control system 30 may receive the starting instruction from the machine body control system 20 through cooperation between the machine body control system 20 and the jig control system 30.

As in the foregoing, according to the construction information integration system 200 and the construction information integration method M200 according to the second embodiment of the present invention, the construction member information acquiring unit 210 acquires construction member information, the plan information generation unit 120 generates first plan information (second plan information) including or separately from the construction member information, and the transmission unit 130 transmits the first plan information (second plan information) to the machine body control system 20 (jig control system 30), which is a different system from the construction information integration system 200. The transmission unit 130 transmits the construction member information to the terminal device 40, and the receiving unit 140 receives the preparation completion information. The transmission unit 130 transmits a starting instruction to the machine body control system 20 (jig control system 30) on the basis of the preparation completion information. In this way, the machine body control system 20 (jig control system 30) can control the operation of the crane (jig) after the preparation has been properly completed on the site. In other words, the construction information integration system 200 can properly support the automated operation of the crane (jig).

The embodiments of the present invention have been specifically described, but the same is only a description of the embodiments. The above description is intended to facilitate understanding of the invention and is not intended to limit the interpretation of the invention. The scope of the invention is not limited by the embodiments but should be interpreted broadly to the extent that a person skilled in the art can understand. The elements and arrangement, materials, conditions, shapes and sizes thereof are not limited by those shown by way of illustration but can be varied as appropriate. The features and configurations from the different embodiments can be partially replaced or combined between each other.

Reference Signs List

| | |
|---|---|
| 11 | Member management system |
| 20 | Machine body control system |
| 30 | Jig control system |
| 31 | Sensor |
| 32 | Reference direction marker |
| 33 | Direction finding marker |
| 34 | Mobile station |
| 35 | Reference station |
| 40 | Terminal device |
| 100, 200 | Construction information integration system |
| 110 | Architectural information acquiring unit |
| 120 | Plan information generation unit |
| 130 | Transmission unit |
| 140 | Receiving unit |
| 150 | Progress management unit |
| 210 | Construction member information acquiring unit |
| M100, M200 | Construction information integration method |
| S110 to S150, | Steps in construction information |
| S210 to S230 | integration methods M100 and M200 |

1. A construction information integration system managing automated operation of a crane, the system comprising:
an architectural information acquiring unit that acquires architectural information including information related to a design, a construction member, and a construction plan of a building to be constructed;
a plan information generation unit that generates, on the basis of the architectural information, first plan information including at least installation coordinates and order of installation for the construction member; and
a first transmission unit that transmits the first plan information to a machine body control system provided as a separate system from the construction information integration system to control operation of the crane.

2. The construction information integration system according to claim 1, wherein
the first plan information comprises restriction range information that indicates an area where entry has to be avoided and which is used by the machine body control system to calculate a path along which the construction member is transported by the crane to the installation coordinates.

3. The construction information integration system according to claim 1, wherein the plan information generation unit generates second plan information including at least an installation direction for the construction member on the basis of the architectural information,
the construction information integration system further comprising a second transmission unit that transmits the second plan information to a jig control system that controls operation of a jig associated with the crane.

4. The construction information integration system according to claim 1, further comprising:
a first receiving unit that receives, from the machine body control system, an operation log of the crane related to an installation status of the construction member; and
a progress management unit that manages progress with respect to the construction plan on the basis of the operation log of the crane.

5. The construction information integration system according to claim 4, wherein the operation log of the crane includes information related to identification information that can be used to identify the construction member, starting time and ending time for the operation of the crane, and the installation coordinates of the construction member.

6. The construction information integration system according to claim 4, further comprising a second receiving unit that receives an operation log of the jig related to an installation status of the construction member from a jig control system that controls the operation of the jig associated with the crane, wherein
the progress management unit manages progress with respect to the construction plan on the basis of the operation log of the jig.

7. The construction information integration system according to claim 6, wherein
the operation log of the jig includes information related to identification information that can be used to identify the construction member, starting time and ending time for the operation of the jig, and an installation direction for the construction member.

8. The construction information integration system according to claim 4, wherein the progress management unit indicates progress including at least one of overall progress about a project, daily progress, and progress in units of floors.

9. The construction information integration system according to claim 1, further comprising:
a construction member information acquiring unit that acquires construction member information related to the construction member provided with the identification information that can be used for identification; and
a third transmission unit that transmits the construction member information to a terminal device.

10. The construction information integration system according to claim 1, further comprising a third receiving unit that receives preparation completion information that indicates that the identification information that is provided to the construction member and that can be used for identification has been confirmed by the terminal device, wherein
the first transmission unit transmits, to the machine body control system, a starting instruction indicating the start of operation of the crane on the basis of the preparation completion information and the first plan information.

11. The construction information integration system according to claim 3, wherein
the first plan information and the second plan information include the same information.

12. A construction information integration method carried out by a construction information integration system managing automated operation of a crane, the method comprising the steps of:
acquiring architectural information including information related to a design, a construction member, and a construction plan of a building to be constructed;
generating first plan information including at least installation coordinates and order of installation for the construction member on the basis of the architectural information; and
transmitting the first plan information to a machine body control system provided as a separate system from the construction information integration system to control operation of the crane.

13. A construction information integration program causing a computer to carry out a construction information integration method managing automated operation of a crane, the program executing the steps of:
acquiring architectural information including information related to a design, a construction member, and a construction plan of a building to be constructed;
generating first plan information including at least installation coordinates and order of installation for the construction member on the basis of the architectural information; and
transmitting the first plan information to a machine body control system provided as a separate system from the construction information integration system to operation of the crane.
